(19) United States
(12) Patent Application Publication
(10) Pub. No.: US 2012/0013442 A1
(43) Pub. Date: Jan. 19, 2012

(54) POWER CORD

(75) Inventor: YU-LUNG LEE, MIAOLI COUNTY (TW)

(73) Assignee: POWERTECH INDUSTRIAL CO., LTD., Taipei Hsien (TW)

(21) Appl. No.: 12/889,872

(22) Filed: Sep. 24, 2010

(30) Foreign Application Priority Data
Jul. 16, 2010 (TW) 99123462

(51) Int. Cl. G08B 5/22; H05K 7/00

(52) U.S. Cl. 340/6.1; 307/149

(57) ABSTRACT

A power cord is disclosed. The power cord includes a plug unit, a cable unit, a device connecting unit, and a control unit. The control unit could be installed in the plug unit or the device connecting unit. The control unit has a detecting module, a processing module, and a wireless communication module. The detecting module is used for detecting a power transmitting status of the power cord such as voltage and current, and transmitting the power transmitting status to the processing module for the generation of a power source data, which is prepared by the processing module. The power source data may be delivered to external devices through the wireless communication module so that an objective of efficient power source management may be achieved.

### BACKGROUND OF THE INVENTION

1. Field of the Invention

The field of the invention is generally related to a power cord, and, more particularly, to a power cord which could detect a current status and have wireless communication for providing functions such as controlling, management, recording, and monitoring.

2. Description of Related Art

For managing and monitoring a power usage, conventional electronic equipments are often equipped with an extra electricity meter or a detecting device. The aforementioned electricity meter and detecting device are to monitor the power usage status before any back-end processing could proceed based on the discovered power usage status. Such conventional electricity meter or detecting device generally occupies space between the electronic equipments and walls in front of which the electronic equipments are placed. However, as power cords of the electronic equipments also take up the same space a limited space would be available for the conventional electricity meter/detecting device, complicating the placement of the electricity meter and the detecting device at the back of the electronic equipments.

### SUMMARY OF THE INVENTION

In accordance with aspects of the present invention, a power cord that is capable of being remotely managed is disclosed. More specifically, the power cord according to the present invention may extract power source data for the electronic equipment while serving as an equivalent of the electricity meter/detecting device, eliminating the necessity of the placement of the electricity meter/detecting device at the back of the electronic equipment.

In order to achieve the aforementioned objective, one embodiment of the present invention provides a power cord having a plug unit, a cable unit, a device connecting unit and a control unit. The plug unit connects with a power source such as alternating current (AC) power and the cable unit is configured to transmit power received from the power source.

The device connecting unit electrically connected with the cable unit is used to connect with electronic equipment and provides the power transmitted from the cable unit to the electronic equipment. The control unit connects with the cable unit and is located in the plug unit or the device connecting unit.

The control unit could detect a power source data of the electricity passing through the cable unit and transmit the power source data via a wireless network. The power source data includes one or combinations of electric current, voltage, watts, apparent power, reactive power, electric power frequency, power factor and watt-hour.

The control unit includes a detecting module, a processing module, and a wireless communication module. The detecting module electrically connected with the cable unit detects the electricity transmitted through the cable unit (i.e., power transmitting data) and transmits the power transmitting data to the processing module. The processing module electrically connected with the detecting module receives and analyzes the power transmitting data from the detecting module before generating the corresponding power source data.

The wireless communication module type could be Bluetooth, Infrared or radio frequency (RF) module and electrically connects with the processing module for transmitting the power source data via the wireless network.

Moreover, control unit could further include an AC/direct current (DC) converter module, a switch module, a storage module and a status indicating module. The AC/DC converter module electrically connects with cable unit and the processing module for supplying a DC signal to the processing module for the processing module to properly operate. The switch module electrically connects with the processing module and is in a series connection with the cable unit. The switch module controls whether the power from the power source could be delivered to the connected electronic equipment via the cable unit based on a conducting signal or a cutting off signal.

The storage module electrically connected with the processing module. The storage module could be a volatile memory or a non-volatile memory. The status indicating module electrically connects with the processing module. The status indicating module includes an indicator light to indicate whether the control unit is in a first mode. Furthermore, the status indicating module includes an indicator button when pressed for activating the control unit.

In short, the power cord according to the present invention is equipped with the detecting module for detecting the power transmitting status and the wireless communication module for transmitting the power source data to external devices for further processing. Therefore, no additional circuitry implementing the detecting device/electricity meter is necessary.

For further understanding of the invention, reference is made to the following detailed description illustrating the embodiments and examples of the invention. The description is only for illustrating the invention, not for limiting the scope of the claim.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompany drawings, wherein like reference numerals refer to like parts throughout the various views unless otherwise specified.

FIG. 1 is a schematic diagram of a power cord in accordance with an embodiment of the invention.

FIG. 2 is a functional block diagram of a power cord in accordance with an embodiment of the invention.

FIG. 3 is a function block diagram of a power cord in accordance with another embodiment of the invention.

FIG. 4 is a schematic diagram of a power cord in accordance with another embodiment of the invention.

FIG. 5 is a schematic diagram of a power cord in accordance with another embodiment of the invention.

### DETAILED DESCRIPTION OF THE. PREFERRED EMBODIMENTS

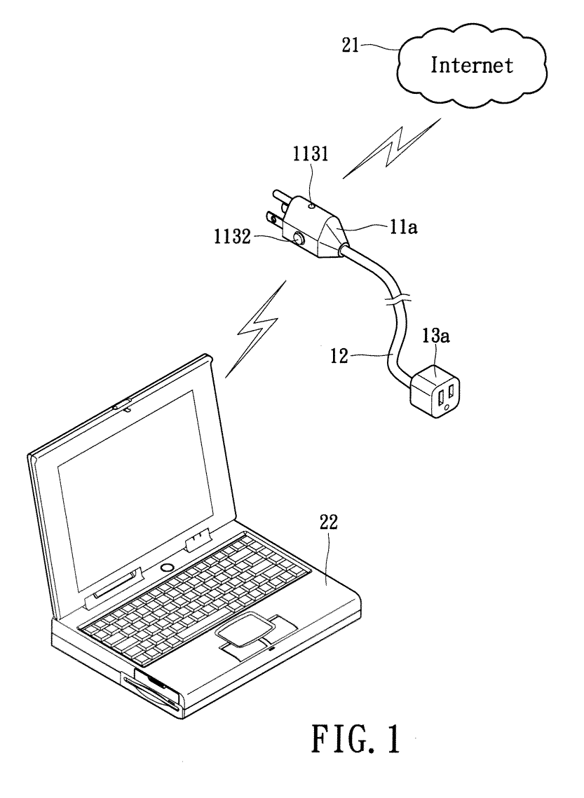

Please refer to FIG. 1, which illustrates a schematic diagram of a power cord in accordance with an embodiment of the invention. The power cord includes a plug unit 11a, a cable unit 12 and a device connecting unit 13a. In one implementation, the plug unit 11a could be an alternating current (AC) power plug used to be plugged into an AC power outlet for receiving an AC power.

The cable unit 12 could be a wire having one side thereof electrically connected with the plug unit 11a for receiving the AC power from the plug unit 11a. The device connecting unit 13a, meanwhile, may be electrically connected with the other side of the cable unit 12, and electronic equipment. Therefore, that the power received from the cable unit 12 may be delivered to the electronic equipment.

In one implementation, the device connecting unit 13a could be an AC power outlet for the AC power plug of the electronic equipment to be plugged.

It is worth noting that the power cord in FIG. 1 may further include a control unit (not shown) for detecting a power transmitting status, such as a voltage, a current, and power consumption, of the power transmitted via the power cord. The control unit installed in the plug unit 11a and electrically connected with the cable unit 12.

The control unit detects the power transmitting status and delivers a power source data according to the power transmitting status to an external device 22 or other electronic devices via the internet 21, A computer shown in the FIG. 1 is configured to detect the power source data through the control unit, and deliver the detected power source data to an external power monitoring device in a wireless fashion. Therefore, the usage of the power source could be managed more efficiently.

The control unit may further include a status indicating module, which is not shown in FIG. 1, including an indicator 1131 and an indicating button 1132. In one implementation, the indicator 1131 could be installed on the plug unit 11a to indicate whether the control unit properly operates. In other words, the indicator 1131 may be indicating that the control unit operates in a first mode (e.g., normally operating mode). The indicating button 1132 may be also located on the plug unit 11a for activating the control unit when pressed.

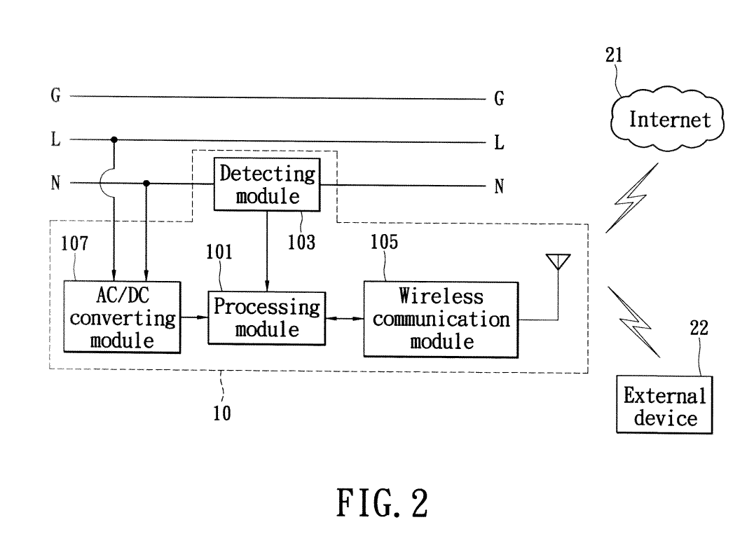

Please refer to FIG. 2, which illustrates a functional block diagram of a power cord in accordance with an embodiment of the invention. A control unit 10 in the power cord has a processing module 101, a detecting module 103 and a wireless communication module 105. The detecting module 103 could be an electric current detecting module, a voltage detecting module or a power consumption detecting module. The detecting module 103 may be electrically connected to a power transmission path of the power cord to detect the power transmitting status of the power cord. The power transmitting status includes values of current, voltage, and/or power consumption. The detecting module 103 may be configured to deliver the power transmitting status to the processing module 101.

The processing module 101 may be configured to process the power transmitting status when receiving the power transmitting status from the detecting module 103. A power source data may be generated accordingly based on the received power transmitting data and may be delivered to the wireless communication module 105. The power source data could be one or combination of the current, voltage, watts, apparent power, reactive power, electric power frequency, power factor, and watt-hour.

The wireless communication module 105 could be a Bluetooth module, radio frequency communication module or infrared communication module. The wireless communication module may be electrically connected with the processing module 101 for receiving the power source data delivered from the processing module 101. The wireless communication module 105 may be configured to transmit the power source data to the Internet 21 or the external device 22 such as a computer, a power source recorder, a power source monitor or a hand-held controller. Therefore, the power source may be remotely managed based on the power source data delivered to the Internet 21 or the external device 22.

In addition, the control unit 10 of the power cord further includes an AC/DC converter unit 107 electrically connecting with the cable unit 12 of the power cord. The AC/DC converter unit 107 is used for converting an AC signal to a DC signal and delivering the DC signal to the processing module 101 for the processing module 101 to operate.

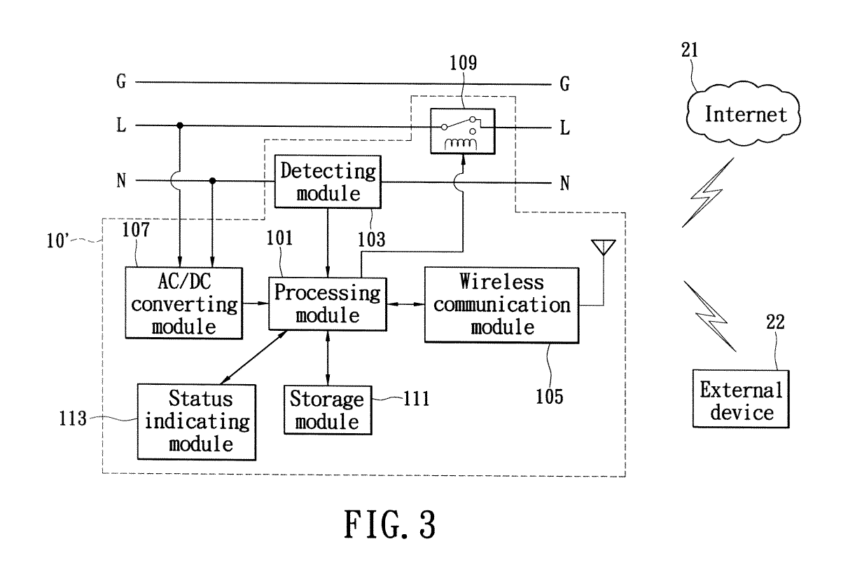

Please refer to the FIG. 3, which illustrates a functional block diagram of a power cord in accordance with another embodiment of the invention. A control unit 10 also includes a processing module 101, a detecting module 103 and a wireless communication module 105. The control unit 10 in FIG. 3 further includes a switch module 109 such as a relay or an electronic switch such as a transistor. The switch module 109 may be electrically connecting with the processing module 101 and in a series connection with the cable unit 12 of the power cord. Thus, the processing unit 101 may control whether to cause the electricity to be transmitted to the electronic equipment based on on/off of the switch control module 109. When any occurrence of anomaly of the power source takes place (e.g., the voltage/current is overly high or the power consumption reaches a predetermined threshold), the processing unit 101 may receive a cutting-off signal from the switch module 109 before stopping the electricity to be further delivered to the electronic equipment.

Furthermore, the control unit 10 could further include an AC/DC converter module 107, a storage module 111 and a status indicating module 113. The AC/DC converter unit 107 is used for converting the AC signal to the DC signal and delivering the DC signal to the processing module 101 for to the processing module 101 to operate. The storage module 111 could be a volatile memory or a non-volatile memory such as Flash Memory, Random Access Memory or Electrically-Erasable Programmable Read-Only Memory electrically connecting to the processing module 101 for storing the power source data.

The status indicating module 113, which is electrically connecting the processing module 101, could further include an indicator and an indicating button. The indicator could be a Light Emitting Diode (LED) connecting with the processing module 101 to indicate whether the control unit 10 of the power cord is in a first mode (or in other words, the control unit 10 operates properly). For example, when the control unit 10 is in the first mode the indicator is emitting; otherwise, the indicator may be switched off. The indicating button is also electrically connecting to the processing unit 101 for activating the control unit 10.

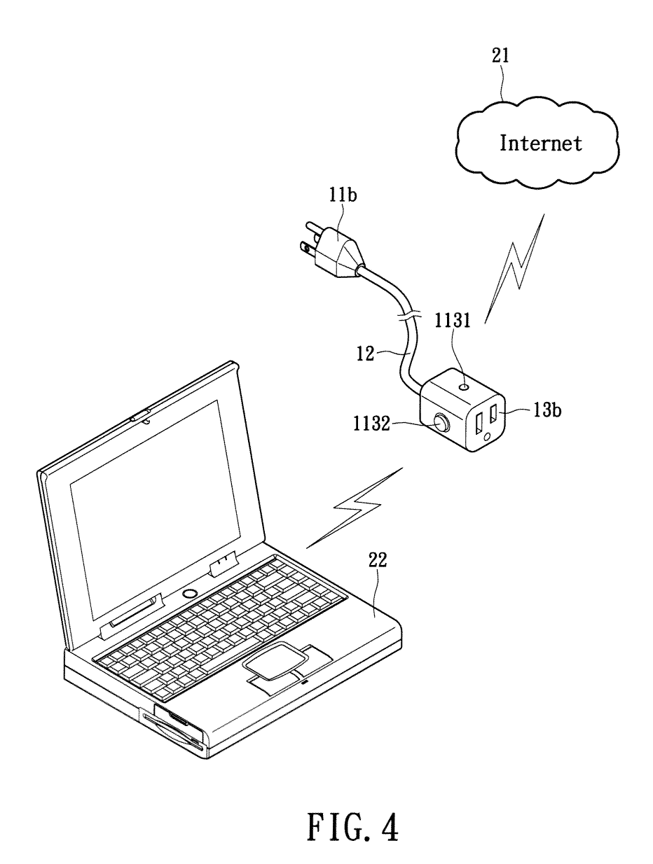

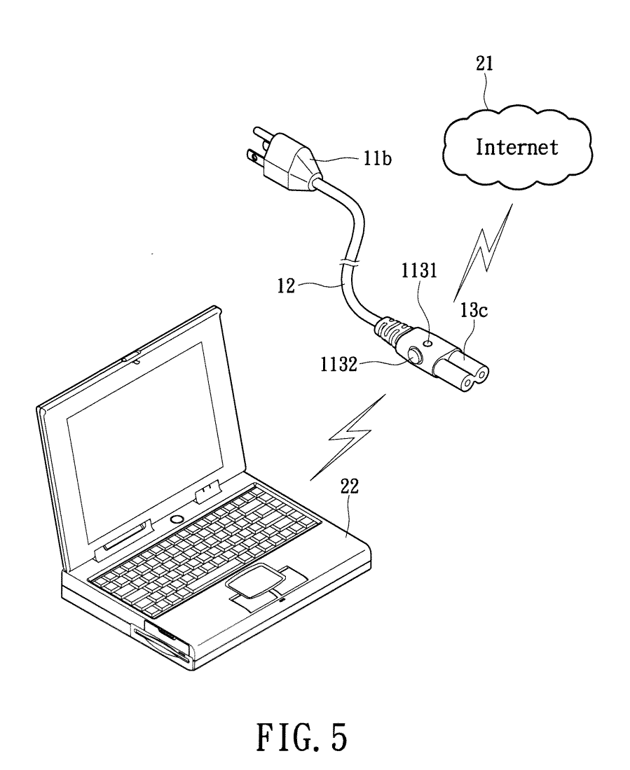

Please refer to FIG. 4 and FIG. 5, which illustrate a schematic diagram of a power cord in accordance with another embodiment of the invention. In FIGS. 4 and 5, the control unit 10 may be installed in the device connecting units 13b and 13c. Both control units 10 in FIGS. 4 and 5 may be equipped with the indicator 1131 and the indicating button 1132 and may effective control the power usage of the connected electronic equipment by detecting the power transmitting status and generating the power source data before delivering the power source data via a wireless communication. The device connecting unit 13b may be an AC socket and the device connecting unit 13c may be an international electro-technical commission (IEC) connecting module such as C6 and C8 connecting port. It is worth noting that the device connecting units 13b and 13c could be of any other types of connectors.

The present invention may extract the power source data indicative of the power transmitting status for the power cord and may further deliver the power source data to an external device for the additional processing. In doing so, the power source may be more effectively managed and the power usage of the electronic device connected to the power source through the power cord according to the instant disclosure may be more efficient.

Some modifications of these examples, as well as other possibilities will, on reading or having read this description, or having comprehended these examples, will occur to those skilled in the art. Such modifications and variations are comprehended within this invention as described here and claimed below. The description above illustrates only a relative few specific embodiments and examples of the invention. The invention, indeed, does include various modifications and variations made to the structures and operations described herein, which still fall within the scope of the invention as defined in the following claims.

What is claimed is:

1. A power cord, comprising:
a plug unit connects with a power source;
a cable unit electrically connecting with the plug unit for transmitting a power received from the power source;
a device connecting unit electrically connecting with the cable unit for connecting an electronic device and transmitting the power from the cable unit to the electronic device; and
a control unit electrically connected with the cable unit and installed in the plug unit comprising:
a detecting module electrically connecting with the cable unit for detecting a power transmitting status of the cable unit;
a processing module electrically connecting with the detecting module for processing the power transmitting status and generating a power source data; and
a wireless communication module electrically connected with the processing module for transmitting the power source data to an external device or an Internet via a wireless communication.

2. The power cord of claim 1, wherein the wireless communication module is one or combinations of a radio frequency (RF) communication module, an Infrared communication module and a Bluetooth communication module.

3. The power cord of claim 1, wherein the control unit further includes an alternating current (AC)/direct current (DC) converter module electrically connecting with the processing module and the cable unit wherein the AC/DC converter module is configured to a direct current to the processing module.

4. The power cord of claim 1, wherein the control unit further includes a switch module electrically connecting with the processing module and in a series connection with the cable unit for receiving a conducting signal or a cutting off signal from the processing module before the cable unit transmits the power to the device connecting unit.

5. The power cord of claim 1, wherein the control unit further includes a status indicating module electrically connecting with the processing module wherein the status indicating module includes a status indicator for indicating whether the control unit operates in a first mode, and an indicating button for being pressed to activate the control unit.

6. A power cord, comprises;
a plug unit is used to connect a power source;
a cable unit electrically connecting the plug unit for transmitting a power received from the power source;
a device connecting unit electrically connecting with the cable unit for connecting an electronic equipment and transmitting the power from the cable unit to the electronic equipment; and
a control unit electrically connecting with the cable unit and installed in the device connecting unit comprising:
a detecting module electrically connecting with the cable unit for detecting a power transmitting status for the power transmitted by the cable unit;
a processing module electrically connecting with the detecting module for processing the power transmitting status received from the detecting module and generating a power source data; and
a wireless communication module electrically connected with the processing module for transmitting the power source data to an Internet or an external device via a wireless communication.

7. The power cord of claim 6, wherein the device connecting unit is an alternating current (AC) socket or an international electro-technical commission (IEC) connecting module.

8. The power cord of claim 6, wherein the wireless communication module is one or combinations of a RF communication module, an Infrared communication module and a Bluetooth communication module.

9. The power cord of claim 6, wherein the control unit further includes a switch module electrically connecting with the processing module and in a series connection with the cable unit for receiving a conducting signal or a cutting off signal from the processing module to determine whether the cable unit transmits the power to the device connecting unit.

10. The power cord of claim 6, wherein the control unit further includes a status indicating module electrically connecting with the processing module and having a status indicator and an indicating button, wherein the indicator is used for indicating whether the control unit is in a first mode and the indicating button is for being pressed to activate the control unit.
